(19) United States
(12) Patent Application Publication
(10) Pub. No.: US 2025/0015117 A1
(43) Pub. Date: Jan. 9, 2025

(54) PADS FOR IMAGE SENSORS AND RELATED METHODS

(71) Applicant: SEMICONDUCTOR COMPONENTS INDUSTRIES, LLC, Scottsdale, AZ (US)

(72) Inventor: Shou-Chian HSU, Zhubei City (TW)

(73) Assignee: SEMICONDUCTOR COMPONENTS INDUSTRIES, LLC, Scottsdale, AZ (US)

(21) Appl. No.: 18/347,702

(22) Filed: Jul. 6, 2023

(51) Int. Cl. H01L 27/146

(52) U.S. Cl. CPC H01L 27/14636; H01L 27/14685

(57) ABSTRACT

Implementations of a pad for an image sensor may include a pad base coupled in a pad opening formed in an image sensor die and a layer of metal directly coupled to the pad base extending to a top surface of the pad opening. The pad base may directly couple with a first metallization layer of the image sensor die.

### BACKGROUND

### 1. Technical Field

Aspects of this document relate generally to semiconductor packages, such as packages for image sensor semiconductor devices.

### 2. Background

Semiconductor packages have been devised to allow for formation of electrical interconnects between semiconductor die and a circuit board or motherboard to which the semiconductor packages are attached. Various semiconductor packages also work to protect the semiconductor die from environmental factors like humidity or electrostatic discharge.

### SUMMARY

Implementations of a pad for an image sensor may include a pad base coupled in a pad opening formed in an image sensor die; and a layer of metal directly coupled to the pad base extending to a top surface of the pad opening. The pad base may directly couple with a first metallization layer of the image sensor die.

Implementations of a pad for an image sensor may include one, all, or any of the following:

The layer of metal may be a single layer of metal.

The layer of metal may be electroless plated.

The pad base may include aluminum.

The layer of metal may be nickel.

The pad may include a layer of gold directly coupled to the layer of metal.

The perimeter of the layer of metal may be within a perimeter of the pad base.

Implementations of a method of forming a pad for an image sensor may include providing a pad base coupled in a pad opening formed in an image sensor die; and electrolessly plating a layer of metal directly onto the pad base to a top surface of the pad opening.

Implementation of a method of forming a pad for an image sensor may include one, all, or any of the following:

Electrolessly plating the layer of metal may include electrolessly plating nickel.

The method may include forming a layer of gold directly on the layer of metal.

The method may include applying bonding glue directly over the layer of metal while bonding an optically transmissive cover over the image sensor die.

A cavity wall may be included between the bonding glue and the optically transmissive cover.

The layer of metal may be level with a plane formed by the top surface of the pad opening.

The layer of metal may be substantially level with a plane formed by the top surface of the pad opening.

Implementations of a method of forming a pad for an image sensor may include forming a pad opening in an image sensor die; forming a pad base in the pad opening; and electrolessly plating a layer of metal onto the pad base substantially level with a top surface of the pad opening.

Implementations of a method of forming a pad for an image sensor may include one, all, or any of the following:

Electrolessly plating the layer of metal may include electrolessly plating nickel.

The method may include forming a layer of gold directly on the layer of metal.

The method may include applying bonding glue directly over the layer of metal while bonding an optically transmissive cover over the image sensor die.

A cavity wall may be included between the bonding glue and the optically transmissive cover.

The perimeter of the layer of metal may be within a perimeter of the pad base.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view and a detail view of an implementation of an image sensor die with a pad opening;

FIG. 2 is a cross sectional view and detail view of an implementation of an image sensor die with a layer of metal directly coupled to a pad base;

FIG. 3 is a cross sectional view of an implementation of an image sensor die with a filled pad opening coupled to an optically transmissive cover;

FIG. 4 is a cross sectional view of an image sensor die with a pad opening;

FIG. 5 is a cross sectional view of an image senor die with a filled pad opening;

FIG. 6 is a cross sectional view of an optically transmissive cover;

FIG. 7 is a cross sectional view of an optically transmissive cover with a cavity wall and bonding glue coupled thereto;

FIG. 8 is a cross sectional view of the image sensor die of FIG. 5 in proximity to the optically transmissive cover of FIG. 7 prior to bonding;

FIG. 9 is a cross sectional view of the image sensor die of FIG. 5 and the optically transmissive cover of FIG. 7 following bonding;

FIG. 10 is a cross sectional view of a bonded image sensor die and optically transmissive cover following additional packaging operations including interconnect formation; and

FIG. 11 is a cross sectional view of the bonded image sensor die of FIG. 10 following a singulation operation.

### DESCRIPTION

This disclosure, its aspects and implementations, are not limited to the specific components, assembly procedures or method elements disclosed herein. Many additional components, assembly procedures and/or method elements known in the art consistent with the intended pads for image sensors will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such pads for image sensors, and implementing components and methods, consistent with the intended operation and methods.

In various image sensor devices, the absorption of light in silicon depends on the thickness of the silicon. To achieve desired levels of quantum efficiency, thicker silicon layers are used. In some image sensor devices, the silicon is formed as an epitaxial layer. For certain wavelengths of light, like near infrared, thicker silicon is needed to assist with achieving an image sensor device that has the desired quantum efficiency level. Because the epitaxial silicon is grown after formation of the back end layers of the image sensor device, forming electrical connections on the side of the device where the epitaxial silicon has been formed means the entire thickness of the epitaxial layer is removed to form a pad opening for reaching a bond pad. Where the thickness of the epitaxial layer is in microns, attempting to bond to pads that are 3 microns, 6 microns, 8 microns or deeper into the material of the image sensor becomes challenging.

Furthermore, even where the pad is used only for probe or other electrical testing prior to additional semiconductor packaging steps, the space formed by the pad opening can create voids where bonding glue used to couple the image sensor device to a cavity wall of an optically transmissive cover fails to fully fill the pad opening. In various image sensor devices, the use of a photoresist or other organic material has been used to fill the pad opening. However, the ability to of the photoresist or other organic material to fully fill the pad opening depends on the process capability of the coating/application technique used to apply the photoresist, so the risk of voids is not entirely eliminated.

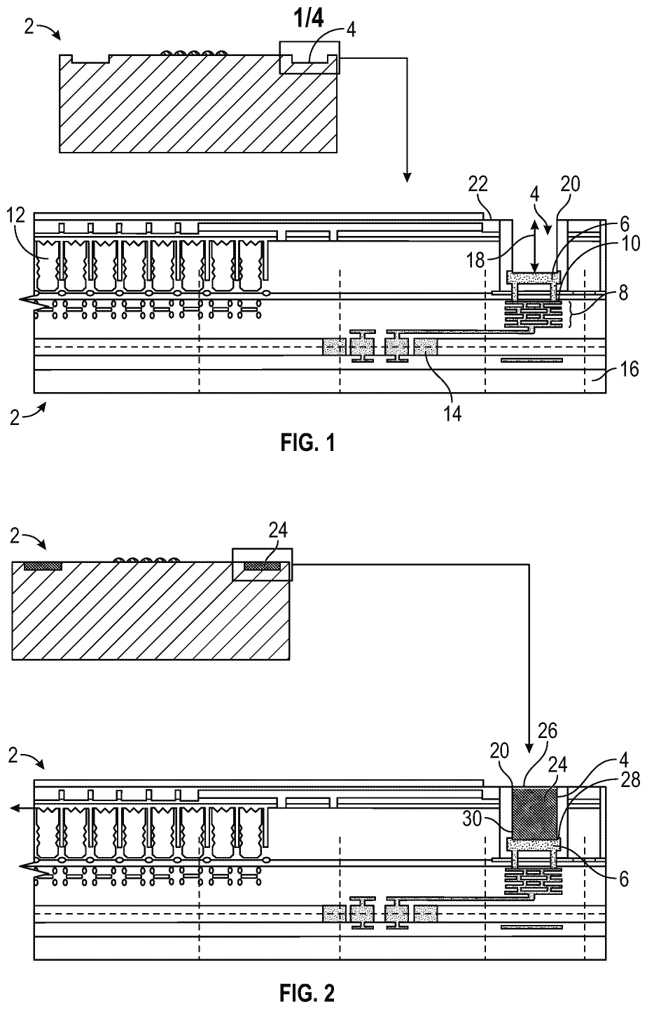

Referring to FIG. 1, a cross sectional view of an implementation of an image sensor device 2 is illustrated in a die-level view and a detail view showing the structure of pad opening 4. The die-level view shows the structure of the image sensor device 2 at one level of detail which intentionally exaggerates the size of the pad opening 4 for the purposes of better illustration. The detail view shows the pad opening 4 in a more realistic proportion relative to the other structures of the image sensor device 2. As illustrated, the pad opening 4 includes a pad base 6 that has been formed in the bottom of the pad opening and which is electrically coupled with metallization layers 8 of the image sensor device 2. In this implementation, because the image sensor device 2 is a back-side integrated (BSI) image sensor device, the pad base 6 electrically couples with the first metallization layer 10 of the device. In this particular implementation of an image sensor device 2, the pad base 6 is used for electrical testing purposes prior to bonding an optically transmissive cover. Other image sensor devices like a pixel array 12 and other electrical interconnects and associated pads 14 are included along with other electrical routing structures that allow this image sensor device to be hybrid bonded to an another semiconductor device 16 like a digital signal processor other semiconductor device.

The height 18 of the pad opening 4 creates a significant space to fill between the surface of the pad base 6 and the top 20 of the pad opening 4. The top 20 of the pad opening 4 forms a plane parallel with the largest planar surface 22 of the image sensor device. If the pad opening 4 can be filled, void free, up to the plane formed by the top 20 of the pad opening 4, then no voids for the bonding glue would exist later in the process. In various implementations, the pad base 6 may be made of aluminum though in other implementations, other metals may be employed.

Referring to FIG. 2, the image sensor device 2 is illustrated in die-level and detail views again, showing that the entire pad opening 4 has been filled with a layer of metal 24 up to the top 20 of the pad opening, creating a planarized surface. Because making a direct electrical connection with the pad base 6 may be difficult to do with the pad base buried in the depth of the pad opening and because of bonding of the image sensor die, the layer of metal 24 is formed/deposited using electroless plating. As illustrated in FIG. 2, the layer of metal 24 may also include one or more additional layers of other metals 26 directly coupled to the layer of metal 24 such as, by non-limiting example, gold, palladium, copper, any combination thereof, or any other electrolessly platable or otherwise depositable metal material. This one or additional layers of metal 26 may be to form a desired surface finish on the layer of metal 24. In other implementations, however, the layer of metal 24 may be only a single layer of metal material formed using electroless plating. In a particular implementation, the layer of metal 24 is made of nickel.

By inspection in FIG. 2, the pad base 6 has a perimeter 28 because it is a three dimensional object with dimensions that extend into and out of the paper of the cross sectional drawing of FIG. 2. Likewise the layer of metal 24 also has a perimeter 30 which extends into and out of the paper of the cross sectional drawing of FIG. 2. In various implementations, the perimeter 30 of the layer of metal 24 is within the perimeter 28 of the pad base 6. In particular implementations, the perimeter 30 may be at least partially within the perimeter 28 where portions of the perimeter 30 extend over or past the perimeter 28 of the pad base 6. In other implementations, the perimeter 30 of the layer of metal 24 is entirely within the perimeter 30 of the pad base 6, where all portions of the perimeter 30 are physically inside the perimeter 28. In some implementations, the perimeter 30 of the layer of metal 24 may be coextensive with, or the same size as, the perimeter 28 of the pad base 6.

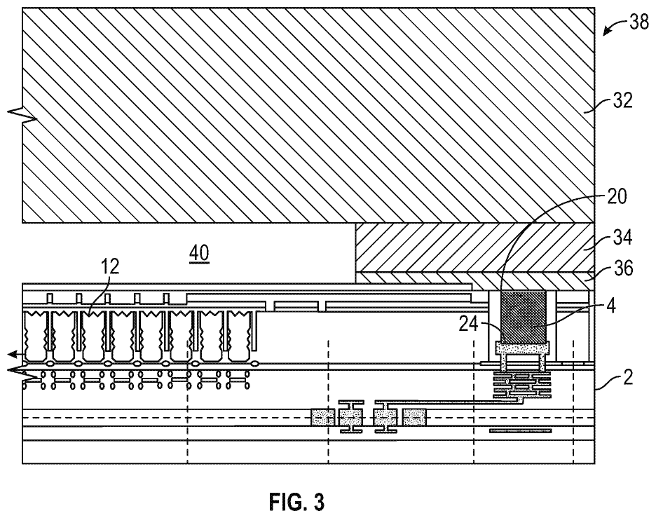

Referring to FIG. 3, the image sensor device 2 is illustrated following bonding of an optically transmissive cover 32 thereto using a cavity wall 34 and bonding glue 36. Note that the bonding glue 36 is able to spread evenly across the entire width of the layer of metal 24 of the pad opening 4 because the layer of metal 24 fills the pad opening up to the top surface 20. While the use of a cavity wall 34 is illustrated in the package implementation 38 of FIG. 3 to form an air gap 40, in other implementations, no air gap 40 may be present. In these gap-less image sensor implementations, the optically transmissive cover may be bonded using a material that extends completely across the image sensor array 12. This material may have a specifically selected index of refraction in some implementations. Because the bonding glue is able to spread evenly across the pad opening 4, voiding in the bonding glue may be prevented.

Implementations of pads for image sensors may be formed using various implementations of methods of forming a pad for an image sensor. While in FIGS. 4-9 implementations of a single image sensor device and optically transmissive cover are illustrated in cross sectional view, the same principles and method elements can also be applied across an entire wafer, substrate, or panel in various implementations. Also, the images in FIGS. 4-9 are similar in detail to the die-level views in FIGS. 1 and 2 which do not necessarily show the various components to actual scale for the purposes of easier illustration.

Referring to FIG. 4, an implementation of an image sensor device 42 is illustrated that shows pad openings 44 and an image sensor array (indicated by microlens array 46). It is understood that more than two pad openings may be present in various image sensor devices and may be distributed in various locations around the outer edge(s) of the image sensor device in various implementations. Within each of the pad openings 44 is a pad base (not illustrated in FIG. 4 for sake of illustration) like any pad base disclosed in this document.

Referring to FIG. 5, the image sensor device 42 is illustrated following filling of the pad openings 44 with layer of metal 48. The process of forming the layer of metal 48 is electroless plating using any metal material disclosed in this document that can be electrolessly plated on the material of the pad bases. As illustrated, the layer of metal 48 is level with a plane formed by the top surface of the pad opening. In some implementations, however, the layer of metal 48 may be substantially level with the plane formed by the top surface of the pad openings 44 as the layer of metal 48 may extend slightly above or below the plane.

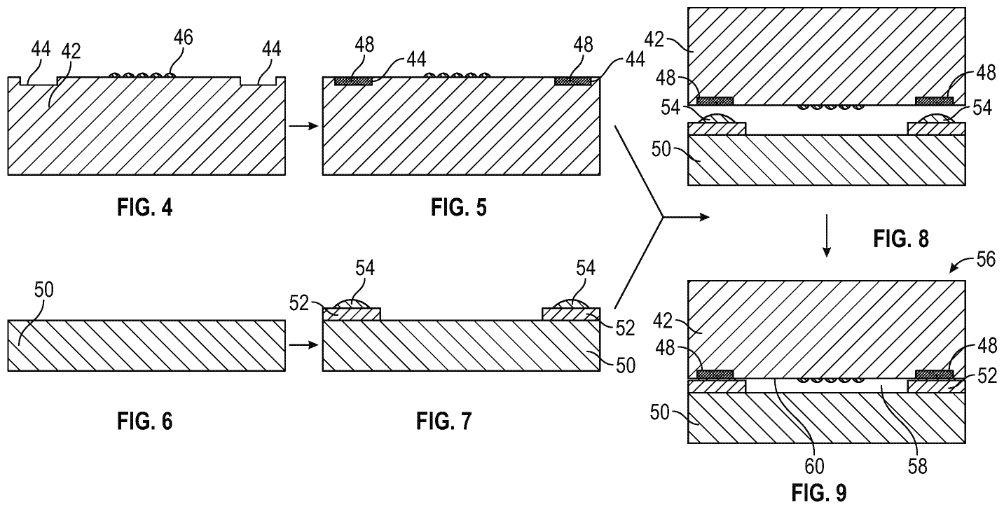

FIG. 6 illustrates an implementation of an optically transmissive cover 50 that is sized to fit over image sensor device 42. Where processing is done at the wafer or substrate level, the optically transmissive cover 50 may take on a corresponding shape with the wafer or substrate to allow for wafer-scale or substrate-scale processing. The material of the optically transmissive cover may be translucent or transparent to the desired wavelength of electromagnetic radiation that the image sensor device 2 is designed to detect. FIG. 7 illustrates the optically transmissive cover 50 following formation/coupling of cavity wall 52 around the perimeter of the optically transmissive cover 50 and then application of bonding glue 54 to the surface of the cavity wall 52. The cavity wall 52 may be formed of a wide variety of materials including, by non-limiting examples, epoxies, resins, optically transmissive organic compounds, optically opaque organic compounds, mold compound, or any other structure capable of bonding with/coupling with the material of the optically transmissive cover 50. In some implementations, the material of the cavity wall 52 may be selected for its ability to chemically bond with the material of the optically transmissive cover 50. In other implementations, the material of the cavity wall 52 may be separately bonded using another glue or other bonding material to the optically transmissive cover.

In the various method implementations, the placement of the bonding glue may be accomplished through use of a wide variety of techniques, including, by non-limiting example, stencil printing, jet printing, contact printing, or any other liquid dispensing technique. The material of the bonding glue may be, by non-limiting example, a thermally cured adhesive, an ultraviolet light (UV) cured adhesive, an evaporatively cured adhesive, any combination thereof, or any other adhesive type. In some implementations, the bonding glue may be optically transmissive (translucent or transparent) or optically opaque.

Referring to FIG. 8, the image sensor device 42 is illustrated adjacent to the optically transmissive cover 50 just prior to the bonding process showing the alignment of the layer of metals 48 with the bonding glue 54. FIG. 9 illustrates the image sensor package 56 following bonding of the optically transmissive cover 60 to the image sensor device 42 using the bonding glue 54 over the layer of metal 48. Air gap 58 is illustrated in the image sensor package 56 formed through the spacing of the cavity 52. As illustrated in FIG. 9, because the layer of metal 48 is level with or substantially level with the largest planar surface of the image sensor device 42, no voiding in the material of the bonding glue 54 is observed.

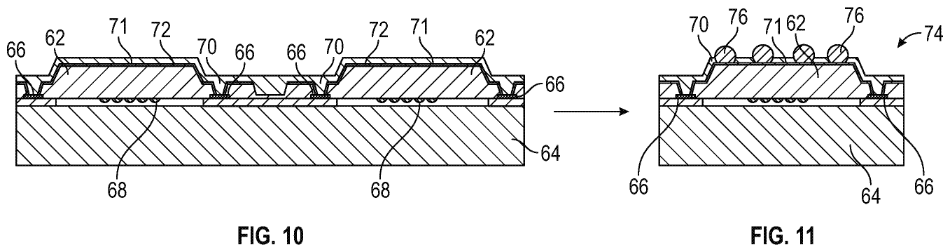

Following formation of the image sensor package 56, some method implementations may employ additional package formation steps to create additional routing layers to permit electrical connections to be formed between the image sensor device (and any other semiconductor devices bonded thereto) and the ultimate circuit board or motherboard to which the image sensor package will be attached. Referring to FIG. 10, two image sensor devices 62 are illustrated following bonding of optically transmissive cover 64 over both devices using bonding glue using any of the materials or method disclosed herein. As illustrated, the image sensor devices 62 include layers of metal 66 formed using any material and method disclosed herein within corresponding pad openings. The side 72 of the image sensor devices 62 opposite pixel arrays 68 have been thinned and etched to expose the pad bases of the layers of metal 66 (not shown for sake of easier illustration). Electrically conductive traces 71 have then been formed to connect the layers of metal 66 and form a redistribution/routing layer along the side 72 of the image sensor devices 62. Solder mask 70 is illustrated as having been deposited over the electrically conductive traces 71 to help passivate the back surface of the image sensor devices 62. These electrically conductive traces 71 may be formed using, by non-limiting example, electroplating, electroless plating, sputtering, or any other method of depositing an electrically conductive material. In this way, electrical connections can be routed from the pixel array 68 side of the image sensor devices 62 to the opposing side 72 of the image sensor devices 62.

FIG. 11 illustrates image sensor package 74 following etching of openings in the solder mask 70 into which balls 76 have been dropped and coupled with the electrically conductive traces 71. These balls 76 may be formed of a wide variety of materials, including, by non-limiting example, solder, copper, any combination thereof, or any other electrically conductive material. In this way the resulting package forms a ball grid array (BGA) that can be used to coupled with the circuit board or motherboard. The traces then route electrical signals from the layers of metal 66 to the balls 76 or from the pixel side of the image sensor device 62 to the balls 76. Following application of the balls 76, the image sensor devices 62 and the optically transmissive cover 64 are then singulated to form image sensor package 74.

In the image sensor device implementation 62 illustrated in FIGS. 10-11, since the pad base material is ultimately exposed and coupled with traces 71, the pad base is not directly located above the metallization layers of the image sensor die 62 as illustrated in the implementations of FIGS. 1-2. Rather, the pad base may be located adjacent to the metallization layers and may be attached to a pad of one of those metallization layers. In both image sensor device implementations, however, the ability to fill the pad opening using electrolessly deposited metal facilitates the needed electrical connections without creating the potential for void formation. This ability to be used in a wide variety of image sensor device configurations and implementations while permitting bonding of the optically transmissive cover by substantially avoiding the creation of voids may be an advantage of the method implementations disclosed herein.

In places where the description above refers to particular implementations of pads for image sensors and implementing components, sub-components, methods and sub-methods, it should be readily apparent that a number of modifications may be made without departing from the spirit thereof and that these implementations, implementing components, sub-components, methods and sub-methods may be applied to other pads for image sensors.

What is claimed is:

1. A pad for an image sensor comprising:
a pad base coupled in a pad opening formed in an image sensor die; and
a layer of metal directly coupled to the pad base extending to a top surface of the pad opening;
wherein the pad base directly couples with a first metallization layer of the image sensor die.

2. The pad of claim 1, wherein the layer of metal is a single layer of metal.

3. The pad of claim 1, wherein the layer of metal is electroless plated.

4. The pad of claim 1, wherein the pad base comprises aluminum.

5. The pad of claim 1, wherein the layer of metal is nickel.

6. The pad of claim 1, further comprising a layer of gold directly coupled to the layer of metal.

7. The pad of claim 1, wherein a perimeter of the layer of metal is within a perimeter of the pad base.

8. A method of forming a pad for an image sensor comprising:
providing a pad base coupled in a pad opening formed in an image sensor die; and
electrolessly plating a layer of metal directly onto the pad base to a top surface of the pad opening.

9. The method of claim 8, wherein electrolessly plating the layer of metal further comprising electrolessly plating nickel.

10. The method of claim 8, further comprising forming a layer of gold directly on the layer of metal.

11. The method of claim 8, further comprising applying bonding glue directly over the layer of metal while bonding an optically transmissive cover over the image sensor die.

12. The method of claim 11, further comprising a cavity wall between the bonding glue and the optically transmissive cover.

13. The method of claim 8, wherein the layer of metal is level with a plane formed by the top surface of the pad opening.

14. The method of claim 8, wherein the layer of metal is substantially level with a plane formed by the top surface of the pad opening.

15. A method of forming a pad for an image sensor comprising:
forming a pad opening in an image sensor die;
forming a pad base in the pad opening; and
electrolessly plating a layer of metal onto the pad base substantially level with a top surface of the pad opening.

16. The method of claim 15, wherein electrolessly plating the layer of metal further comprising electrolessly plating nickel.

17. The method of claim 15, further comprising forming a layer of gold directly on the layer of metal.

18. The method of claim 15, further comprising applying bonding glue directly over the layer of metal while bonding an optically transmissive cover over the image sensor die.

19. The method of claim 18, further comprising a cavity wall between the bonding glue and the optically transmissive cover.

20. The method of claim 15, wherein a perimeter of the layer of metal is within a perimeter of the pad base.
